(19) United States
(12) Patent Application Publication
(10) Pub. No.: US 2008/0136002 A1
(43) Pub. Date: Jun. 12, 2008

(54) MULTI-CHIPS PACKAGE AND METHOD OF FORMING THE SAME

(75) Inventor: Wen-Kun Yang, Hsin-Chu City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/567,767

(22) Filed: Dec. 7, 2006

(51) Int. Cl. H01L 23/02

(52) U.S. Cl. 257/686

(57) ABSTRACT

The present invention provides a structure of multi-chips package comprising: a substrate with a die receiving cavity formed within an upper surface of the substrate and a first through holes structure, wherein a terminal pads is formed under the first through holes structure. A first die is disposed within the die receiving cavity and a first dielectric layer is formed on the first die and the substrate. A first re-distribution conductive layer (RDL) is formed on the first dielectric layer. A second dielectric layer is formed over the first RDL and a second die is attached on the second dielectric layer. A surrounding material surrounds the second die. A third dielectric layer is formed over the second die and the surrounding material. A second re-distribution conductive layer (RDL) is formed on the third dielectric layer. A protection layer is formed over the second RDL.

### FIELD OF THE INVENTION

This invention relates to a structure for system in Package (SIP), and more particularly to a panel scale package (PSP) with SIP.

### DESCRIPTION OF THE PRIOR ART

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support. As a semiconductor become more complicated, the traditional package technique, for example lead frame package, flex package, rigid package technique, can't meet the demand of producing smaller chip with high density elements on the chip,

Currently, multi-chip modules and hybrid circuits are typically mounted on a substrate and the components are typically sealed within a casing. It is common to utilize a multilayer substrate comprised of multiple layers of conductors sandwiched between multiple layers of dielectric material. Multilayer substrates are conventionally fabricated by lamination techniques in which metal conductors are formed on individual dielectric layers, and the dielectric layers are then stacked and bonded together.

The requirement of high density, high performance speeds up the developments of System On Chip (SOC) and System In a Package (SIP). Multi-Chip Module (MCM) is widely used to integrate chips having different functions. Multi-chip package (MCP) or multi-chip module (MCM) technology refers to the practice of mounting multiple, unpackaged integrated circuits (IC's) (“bare die”) on a base material. The multiple dice are “packaged” within an overall encapsulation material or other polymer MCM provides a high density module that requires less space on the motherboard of a computer. The MCM also provides the benefit of integrated functional testing.

Furthermore, because conventional package technologies have to divide a dice on a wafer into respective dies and then package the die respectively, therefore, these techniques are time consuming for manufacture process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dies). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the dice are manufactured and tested on the wafer, and then singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Though the advantages of WLP technique mentioned above, some issues still exist influencing the acceptance of WLP technique. For example, although utilizing WLP technique can reduce the CTE mismatch between IC and the interconnecting substrate, as the size of the device minimizes, the CTE difference between the materials of a structure of WLP becomes another critical factor to mechanical instability of the structure. Furthermore, in this wafer-level chip-scale package, a plurality of bond pads formed on the semiconductor die is redistributed through conventional redistribution processes involving a redistribution layer (RDL) into a plurality of metal pads in an area array type. Solder balls are directly fused on the metal pads, which are formed in the area array type by means of the redistribution process. Typically, all of the stacked redistribution layers are formed over the built-up layer over the die. Therefore, the thickness of the package is increased. This may conflict with the demand of reducing the size of a chip.

Therefore, the present invention provides a multi-chip package for WLP.

### SUMMARY OF THE INVENTION

One aspect of the present invention is to provide a SIP with higher reliability, lower cost advantages.

The present invention provides a structure of multi-chips package comprising: a substrate with a die receiving cavity formed within an upper surface of the substrate and a first through hole structure formed there through, wherein a wiring circuit with terminal pads is formed under the first through hole structure. A first die is disposed within the die receiving cavity, a first dielectric layer is formed on the first die and the substrate. A first re-distribution conductive layer (RDL) is formed on the first dielectric layer, wherein the first RDL is coupled to the first die and the terminal pad through the first through hole structure; a second dielectric layer having openings is formed over the first RDL and a second die is attached on the second dielectric layer. A surrounding material surrounds the second die, wherein the surrounding material has second through hole structure that is aligned to the openings. A third dielectric layer is formed over the second die and the surrounding material. A second re-distribution conductive layer (RDL) is formed on the third dielectric layer, wherein the second RDL is coupled to the bonding pads of second die and the terminal pads through the second through hole structure, and a protection layer is formed over the second RDL.

The first and second RDL are fan out from said first and second dice. The first and second RDLs communicate to said terminal pads downwardly via said first and second through hole structures.

Alternatively, the structure of multi-chips package comprises a substrate with at least two die receiving cavities formed within an upper surface of the substrate to receive at least two dices and through hole structures formed there through, wherein a wiring circuit with terminal pads are formed under the through hole structures. A first die and a second die are disposed within the at least two die receiving cavities, respectively. A first dielectric layer is formed on the first die, the second die and the substrate. A re-distribution conductive layer (RDL) is formed on the first dielectric layer, wherein the RDL is coupled to the first die, the second die and the terminal pads. A second dielectric layer is formed over the RDL as protection layer.

The first dielectric layer includes an elastic dielectric layer. Alternatively, the first dielectric layer comprises a silicone dielectric based material, BCB or PI, wherein the silicone dielectric based material comprises siloxane polymers (SINR), Dow Corning WL5000 series, or composites thereof. The first dielectric layer may comprises a photosensitive (photo-patternable) layer.

The material of the substrate includes epoxy type FR5, FR4, BT, PCB (print circuit board), alloy, glass, silicon, ceramic or metal. Alternatively, the material of the substrate includes Alloy42 (42% Ni-58% Fe) or Kovar (29% Ni-17% Co-54% Fe).

### BRIEF DESCRIPTION OF THE DRAWINGS

FIG. 1 illustrates a cross-sectional view of a structure of stacked fan-out SIP according to the present invention

FIG. 2 illustrates a cross-sectional view of a structure of stacked fan-out SIP according to the present invention.

FIG. 3 illustrates a cross-sectional view of a structure of parallel fan-out SIP according to the present invention.

FIG. 4 illustrates a cross-sectional view of a structure of stacked fan-out SIP according to the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying claims.

The present invention discloses a structure of WLP utilizing a substrate having predetermined circuit with through holes formed therein and a cavity formed into the substrate. A photosensitive material is coated over the die and the pre-formed substrate. Preferably, the material of the photosensitive material is formed of elastic material.

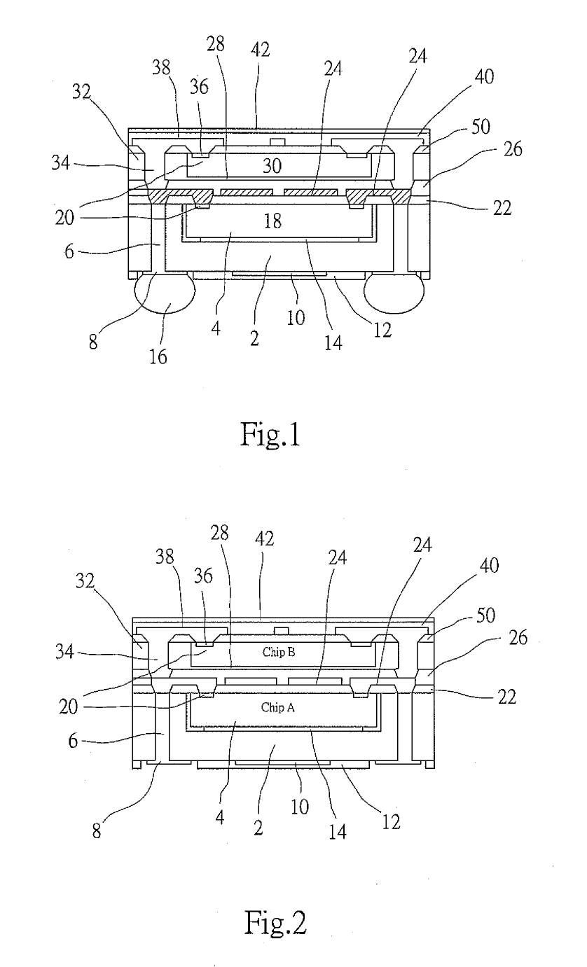

FIG. 1 illustrates a cross-sectional view of panel scale package (PSP) for SIP in accordance with one embodiment of the present invention. As shown in the FIG. 1, the structure of SIP includes a substrate 2 having a die receiving cavity 4 formed therein to receive a die 18. Pluralities of through holes 6 are created through the substrate 2 from upper surface to lower surface of the substrate 2. A conductive material will be re-filled into the through holes 6 for electrical communication. Terminal Pads 8 are located on the lower surface of the substrate and connected to the through holes 6 with conductive material. A conductive circuit trace 10 is configured on the lower surface of the substrate 2. A protective layer 12, for instance solder mask epoxy, is formed over the conductive trace 10 for protection.

The die 18 is disposed within the die receiving cavity 4 on the substrate 2 and fixed by an adhesion (die attached) material 14. As know, contact pads (Bonding pads) 20 are formed on the die 18. A photosensitive layer or dielectric layer 22 is formed over the die 18 and filling into the space between the die 18 and the side walls of the cavity 4. Pluralities of openings are formed within the dielectric layer 22 through the lithography process or exposure and development procedure. The pluralities of openings are aligned to the contact via through holes 6 and the contact or I/O pads 20, respectively. The RDL (re-distribution layer) 24, also referred to as conductive trace 24, is formed on the dielectric layer 22 by removing selected portions of layer formed over the layer 22, wherein the RDL 24 keeps electrically connected with the die 18 through the I/O pads 20. A part of the material of the RDL will re-fills into the openings in the dielectric layer 22, thereby forming contact via metal over the through holes 6 and pad metal over the bonding pad 20. A dielectric layer 26 is formed to cover the RDL 24. The dielectric layer 26 is formed atop of the die 18 and substrate 2 and fills the space surrounding the die 18. Pluralities of openings are formed within the dielectric layer 26 and aligned to the RDL 24 to expose portion of the RDL 24.

A second chip 30 having second pads 36 is attached on the dielectric layer 26 via the adhesion 28. Dielectric material 32 is coated around the second chip 30. The second through holes 34 are formed within the dielectric material 32. A dielectric layer 50 having openings is formed over the second chip (die) 30. The openings are created by using the conventional manner and aligned to the pads of the second chip 30 and the second through holes 34. Conductive material is filled in the second through holes 34, openings of the dielectric layer 26. A second RDL 38 is formed over the dielectric layer 50 and filled in to the openings of the dielectric layer. A protection layer 40 is formed over the second chip 30 and the second RDL 38. A cover 42 is optionally formed over the protection layer 40. The material for the cover could be epoxy, rubber, resin, metal, plastic, ceramic and so on (preferably, the materials is metal for electric shielding and heat dispatch and better top marking quality). Conductive bumps 16 are coupled to the terminal pads 8. The structure with conductive bumps 16 refers to the BGA (Ball Grid Array) type SIP (system in package) or SIP-BGA. If the conductive bumps are omitted, it refers to LGA type SIP (system in package) or SIP-LGA. Please refer to the FIG. 2. The other parts are similar to FIG. 1, therefore, the reference numbers of the similar parts are omitted.

It should be noted that the first chip 18 may communicate with the second chip 30 through first through holes 6, second through hole 34, first RDL 24, second RDL 38. The arrangement is optional. As can be found, the first chip 18 is formed within a cavity 4 to reduce the height of the entire SIP. Both RDL configurations arc Fan-Out type to increase the ball pitch, thereby increasing the reliability and thermal dispassion.

Preferably, the material of the substrate 2 is organic substrate likes epoxy type FR5, BT (Bismaleimide triazine), PCB with defined cavity or Alloy42 with pre etching circuit. The organic substrate with high Glass transition temperature (Tg) are epoxy type FR5 or BT (Bismaleimide triazine) type substrate. The Alloy42 is composed of 42% Ni and 58% Fe, Kovar can be used also, and it is composed of 29% Ni, 17% Co, 54% Fe. The glass, ceramic, silicon can be used as the substrate due to lower CTE.

In one embodiment of the present invention, the dielectric layer 22 is preferably an elastic dielectric material which is made by silicone dielectric based materials comprising siloxane polymers (SINR), Dow Coming WL5000 series, and composites thereof. In another embodiment, the dielectric layer is made by a material comprising polyimides (PI) or silicone resin. Preferably, it is a photosensitive layer for simple process.

In one embodiment of the present invention, the elastic dielectric layer 22 is a kind of material with CTE larger than 100 (ppm/° C.), elongation rate about 40 percent (preferably 30 percent-50 percent), and the hardness of the material is between plastic and rubber. The thickness of the elastic dielectric layer 18 depends on the stress accumulated in the RDL/dielectric layer interface during temperature cycling test.

In one embodiment of the invention, the material of the RDL 24 comprises Ti/Cu/Au alloy or Ti/Cu/Ni/Au alloy; the thickness of the RDL 24 is between 2 um and 15 um. The Ti/Cu alloy is formed by sputtering technique also as seed metal layers, and the Cu/Au or Cu/Ni/Au alloy is formed by electroplating; exploiting the electro-plating process to form the RDL can make the RDL thick enough to withstand CTE mismatching during temperature cycling. The metal pads 20 can be Al or Cu or combination thereof. If the structure of FO-WLP utilizes SINR as the elastic dielectric layer and Cu as the RDL metal, the stress accumulated in the RDL/dielectric layer interface is reduced.

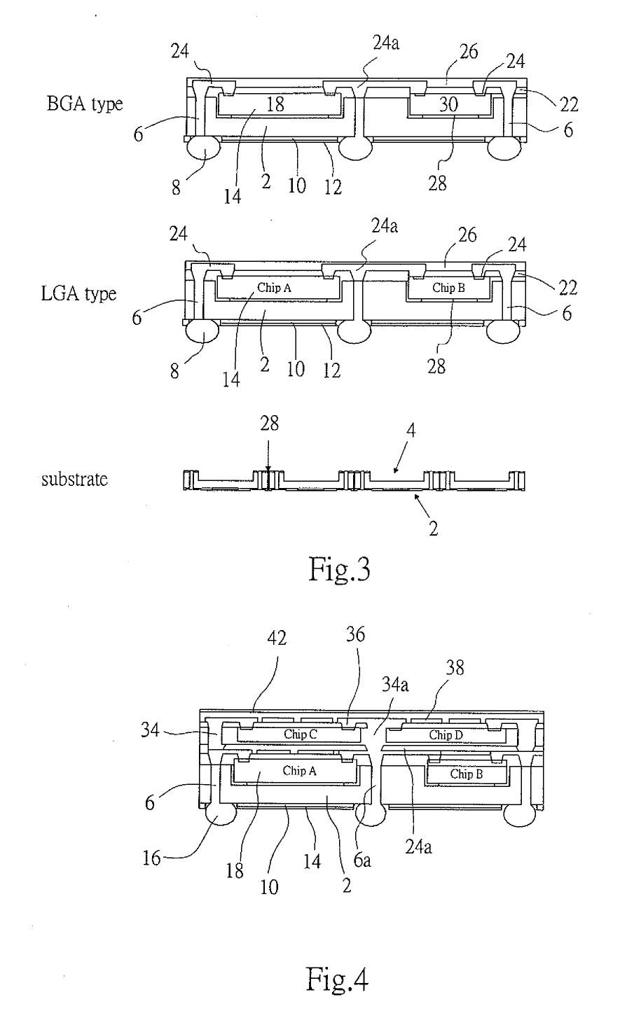

The substrate 2 could be round type such as wafer type, the diameter could be 200, 300 mm or higher. It could be employed for rectangular type such as panel form. FIG. 3 illustrates the pre-formed substrate 2 in cross section. As can be seen from the drawings, the substrates 2 are formed with cavities 4 and built in circuit 10, the through holes structure 6 with metal filled therein. In the upper portion of FIG. 3, the first chip and the second chip are not arranged in stacked configuration. The second chip 30 is locates adjacent to the first chip 18 and both chips are communicated with each other via a horizontal communication line 24a instead of through hole structure. As can be seen, the substrate includes at least two cavities to receive first and second chips, respectively. The BGA and LGA types are shown in the illustration, respectively.

Alternatively, the embodiment of FIG. 4 combines the aspects of FIG. 1 and 3. At least four chips are arranged in the SIP. The upper layer chips may communicates through RDL 36. The lower layer chips may be coupled via RDL 24a, and the upper layer chips may communicate with the lower layer chips via at least the through hole structure 34, 34a.

As shown in FIG. 1-4, the RDLs 24, 38 fan out of the dice and they communicate downwardly toward the terminal pads 8 under the package through hole structure. It is different from the prior art MCM technology which stacks layers over the die, thereby increasing the thickness of the package. However, it violates the rule to reduce the die package thickness. On the contrary, the terminal pads are located on the surface that is opposite to the die pads side. The communication traces are penetrates through the substrate 2 via the through holes and leads the signal to the terminal pad 8. Therefore, the thickness of the die package is apparently shrinkage. The package of the present invention will be thinner than the prior art Further, the substrate is pre-prepared before package. The cavity 4 and the traces 10 are pre-determined as well. Thus, the throughput will be improved than ever. The present invention discloses a fan-out WLP without stacked built-up layers over the RDL.

After the wafer is processed and back-lapped to a desired thickness, the wafer is divided into dice. The substrate is pre-formed with the build in circuit therein and at least one cavity. Preferably, the material for substrate is FR5/BT print circuit board with higher Tg property. The substrate may have cavities with different size to receive different chips, and the depth of the cavities is deeper than the thickness of dice thickness around 20 um to 30 um for die attached material.

The process for the present invention includes providing an alignment tool (plate) with alignment pattern formed thereon. Then, the pattern glues is printed on the tool (be used for sticking the surface of dice), followed by using pick and place fine alignment system with flip chip function to re-distribute the known good dies on the tool with desired pitch. The pattern glues will stick the chips on the tool. Subsequently, the die attached materials is printed on the die back side. Then, the panel bonder is used to bond the substrate on to die back side; the upper surface of substrate except the cavities also be stuck on the pattern glues, then vacuum curing and separate the tool with panel wafer.

Alternatively, the die bonder machine with fine alignment is employed, and the die attached materials is dispensed on the cavity of substrate. The die is placed on to the cavity of substrate. The die attached materials is thermally cured to ensure the die is attached on the substrate.

Once the die is re-distributed on the substrate, then, a clean up procedure is performed to clean the dice surface by wet and/or dry clean. Next step is to coat the dielectric materials on the panel, followed by performing vacuum procedure to ensure there is no bubble within the panel. Subsequently, lithography process is performed to open via and Al bonding pads. Plasma clean step is then executed to clean the surface of via holes and Al bonding pads. Next step is to sputter Ti/Cu as seed metal layers, and then Photo Resistor (PR) is coated over the dielectric layer and seed metal layers for forming the patterns of redistributed metal layers (RDL). Then, the electro plating is processed to form Cu/Au or Cu/Ni/Au as the RDL metal, followed by stripping the PR and wet etching metal to form the RDL metal trace. Subsequently, the next step is to coat or print the dielectric layer and/or to open the contact pads, thereby completing the first layer panel process.

The next procedure is employed to complete the second layer dice; preferably, the thinner die (around 50 um) can get better performance of process and reliability. The process includes print the die attached materials 28 on the back-site of the 2nd layer die 30. The 1st processed panel is bonded with the 2nd layer dice and tools. The next step is to separate the tool with panel after curing, followed by clean the surface of the 2nd layer die and then coating or printing the dielectric materials to filling non-die area surrounding the die and over the die. A dielectric layer 50 is covered over the die 30, followed by opening the pads by lithography process. The next step is to cure the dielectric layer and clean the I/O pads of the 2nd layer die 30 and via through holes. Sputtering Ti/Cu step is performed to form the seed metal layers, and coating PR to form the RDL pattern. Then, electro plating step is used to form Cu/Au into RDL pattern, then, stripping the PR and wet etching seed metal to form RDL metal trace 38. A top dielectric layer 40 is formed to protect the RDL trace 38. A cover layer 42 is formed for top marking.

After the ball placement or solder paste printing, the heat re-flow procedure is performed to re-flow on the substrate side (for BGA type). The testing is executed. Panel wafer level final testing is performed by using vertical probe card. After the testing, the substrate is sawed to singular the package into individual SIP units with multi-chips. Then, the packages are respectively picked and placed the package (device) on the tray or tape and reel.

The advantages of the present invention are.

The substrate is pre-prepared with pre-form cavity; the size of cavity equal to die size plus around 50 um to 100 um per/side; it can be used as stress buffer releasing area by filling the elastic dielectric materials to absorb the thermal mechanical stress due to the CTE difference between silicon die and substrate (FR5/BT). The SIP packaging throughput will be increased (manufacturing cycle time was reduced) due to apply the simple build up layers on top the surface of die and substrate. The circuit with terminal pads are formed on the opposite surface to the dice active surface (pre-formed). The dice placement process is the same as the current process. No core paste (resin, epoxy compound, silicone rubber, etc.) filling is necessary for the present invention. There is no CTE mismatching issue once solder join with mother board PCB and the deepness between die and substrate FR4 is only around ˜20 um-30 um (be used for thickness of die attached materials), the surface level of die and substrate can be the same after die is attached on the cavities of substrate. Only silicone dielectric material (preferably SINR) is coated on the active surface and the substrate (preferably FR45 or BT) surface. The contacting via structure is opened by using photo mask process only due to the dielectric layer (SINR) is photosensitive layer for opening the contacting Via. Vacuum process during SINR coating is used to eliminate the bubble issue. The die attached material is printed on the back-side of dice before substrate be bonded together with dice (chips). The reliability for both package and board level is better than ever, especially, for the board level temperature cycling test, it was due to the CTE of substrate and PCB mother board are identical, so, no thermal mechanical stress be applied on the solder bumps/balls. The cost is low and the process is simple. It is easy to form the combo package (multi dice package).

Although preferred embodiments of the present invention have been described, it will be understood by those skilled in the art that the present invention should not be limited to the described preferred embodiments. Rather, various changes and modifications can be made within the spirit and scope of the present invention, as defined by the following claims.

Having described the invention, the following is claimed:

1. A structure of multi-chips package comprising:
a substrate with a die receiving cavity formed within an upper surface of said substrate and a first through hole structure formed there through, wherein a circuit with terminal pad is formed under said first through hole structure;
a first die disposed within said die receiving cavity;
a first dielectric layer formed on said first die and said substrate;
a first re-distribution conductive layer (RDL) formed on said first dielectric layer, wherein said first RDL is coupled to said first die and said terminal pad through said first through hole structure;
a second dielectric layer having openings formed over said first RDL;
a second die attached on said second dielectric layer;
a surrounding material surround said second die, wherein said surrounding material has second through hole structure that is aligned to said openings;
a third dielectric layer formed over said second die and said surrounding material;
a second re-distribution conductive layer (RDL) formed on said third dielectric layer, wherein said second RDL is coupled to said second die and said terminal pad through said second through hole structure;
a protection layer formed over said second RDL.

2. The structure of claim 1, further comprising conductive bumps coupled to said terminal pad.

3. The structure of claim 1, wherein said dielectric layer includes an elastic dielectric layer.

4. The structure of claim 1, wherein said dielectric layer comprises a silicone dielectric based material, BCB or PI, wherein said silicone dielectric based material comprises siloxane polymers (SINR), Dow Coming WL5000 series, or combination thereof.

5. The structure of claim 1, wherein said first dielectric layer comprises a photosensitive (photo patternable) layer.

6. The structure of claim 1, wherein said first or second RDL is made from an alloy comprising Ti/Cu/Au alloy or Ti/Cu/Ni/Au alloy.

7. The structure of claim 1, wherein said first and second RDL fan out from said first and second dice.

8. The structure of claim 1, wherein said first and second RDLs communicate to said terminal pads downwardly via said first and second through holes structures.

9. The structure of claim 1, wherein the material of said substrate includes epoxy type FR5, FR4, BT, PCB (print circuit board), alloy, glass, silicon, ceramic or metal.

10. The structure of claim 1, wherein the material of said substrate includes Alloy42 (42% Ni-58% Fe) or Kovar (29% Ni-17% Co-54% Fe).

11. A structure of multi-chips package comprising:
a substrate with at least two die receiving cavities formed within an upper surface of said substrate to receive at least two dice and through hole structures formed there through, wherein circuit with terminal pads are formed under said through hole structures;
a first die and a second die disposed within said at least two die receiving cavities, respectively;
a first dielectric layer formed on said first die, said second die and said substrate;
a re-distribution conductive layer (RDL) formed on said first dielectric layer, wherein said RDL is coupled to said first die, said second die and said terminal pads;
a second dielectric layer formed over said RDL.

12. The structure of claim 11, further comprising conductive bumps coupled to said terminal pad.

13. The structure of claim 11, wherein said dielectric layer includes an elastic dielectric layer.

14. The structure of claim 11, wherein said dielectric layer comprises a silicone dielectric based material, BCB or PI, wherein said silicone dielectric based material comprises siloxane polymers (SINR), Dow Corning WL5000 series or composites thereof.

15. The structure of claim 11, wherein said dielectric layer comprises a photosensitive (photo patternable) layer.

16. The structure of claim 11, wherein said first RDL is made from an alloy comprising Ti/Cu/Au alloy or Ti/Cu/Ni/Au alloy.

17. The structure of claim 11, wherein said RDL fan out from said first and second dice.

18. The structure of claim 11, wherein said RDL communicates to said terminal pads downwardly via said through hole structures.

19. The structure of claim 11, wherein the material of said substrate includes epoxy type FR5, FR4, BT, PCB (print circuit board), alloy, glass, silicon, ceramic or metal.

20. The structure of claim 11, wherein the material of said substrate includes Alloy42 (42% Ni-58% Fe) or Kovar (29% Ni-17% Co-54% Fe).

21. A method for forming semiconductor device package comprising:
providing a substrate with a die receiving cavity formed within an upper surface of said substrate and a through hole structure formed there through, wherein circuit with terminal pads are formed under said through hole;
re-distributing said first die on a tool with a desired pitch using a pick and place fine alignment system;
attaching adhesive material on said die back side;
bonding said substrate to said die back side, and separating said tool; coating a first dielectric layer on said die and said substrate;
forming a first RDL on said first dielectric layer;
forming a second dielectric layer over said first RDL;
attaching a second die on said second dielectric layer;
forming a dielectric material to fill the area surrounding said second die;
forming a third dielectric layer over said second die;
forming a second RDL over said third dielectric layer; and
forming a forth dielectric layer to protect said second and second RDL.

22. The method of claim 21, wherein said dielectric layer comprises a silicone dielectric based material, BCB or PI, wherein said silicone dielectric based material comprises siloxane polymers (SINR), Dow Coming WL5000 series, or composites thereof.

23. The method of claim 21, wherein said first dielectric layer comprises a photosensitive (photo patternable) layer.

24. The method of claim 21, wherein said first and said second RDL are made from an alloy comprising Ti/Cu/Au alloy or Ti/Cu/Ni/Au alloy.

25. The method of claim 21, wherein the material of said substrate includes epoxy type FR5, FR4, BT, PCB (print circuit board), alloy, glass, silicon, ceramic or metal.

26. The method of claim 21, wherein the material of said substrate includes Alloy42 (42% Ni-58% Fe) or Kovar (29% Ni-17% Co-54% Fe).
